(19) United States
(12) Patent Application Publication
(10) Pub. No.: US 2006/0273350 A1
(43) Pub. Date: Dec. 7, 2006

(54) Semiconductor integrated circuit

(75) Inventor: Akihiro Nakamura, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/349,958

(22) Filed: Feb. 9, 2006

(30) Foreign Application Priority Data
May 10, 2005 (JP) 2005-137282

(51) Int. Cl. H01L 27/10

(52) U.S. Cl. 257/207

(57) ABSTRACT

Data circuit power supply wiring for supplying power supply voltage to a data circuit and clock circuit power supply wiring for supplying power supply voltage to a clock circuit are connected by a via and power supply wiring formed in a wiring layer that is different from (for example, that is located higher than the data circuit power supply wiring and the clock circuit power supply wiring) a wiring layer in which at least either the data circuit power supply wiring or the clock circuit power supply wiring is formed.

### CROSS-REFERENCE TO RELATED APPLICATION

The disclosure of Japanese Patent Application No. 2005-137282 filed on May 10, 2005 including specification, drawings and claims is incorporated herein by reference in its entirety.

### BACKGROUND OF THE INVENTION

1. Field of the Invention

The present invention relates to a semiconductor integrated circuit including a data circuit for performing signal processing of an input signal and a clock circuit for supplying a clock signal to the data circuit, and more particularly relates to technology for suppressing clock jitter that occurs in a semiconductor integrated circuit.

2. Description of the Related Art

The circuits included in a semiconductor integrated circuit are classified into two groups: data circuits for performing processing of input signals and clock circuits for supplying clock signals to the data circuits. A clock signal input from a PLL circuit or a clock input terminal in a semiconductor integrated circuit propagates through a clock circuit and is input into a data circuit and the data circuit operates in synchronization with the input clock signal.

A conventional semiconductor integrated circuit which performs digital signal processing in synchronization with a signal input from outside is configured as shown in FIG. 7, for example.

The semiconductor integrated circuit 600 includes a clock input terminal 610, data circuits 620, clock circuits 630, a power supply terminal 640, and standard-cell power supply wiring 650.

A clock signal is input into the clock input terminal 610 from outside of the semiconductor integrated circuit 600.

The data circuits 620 are composed of buffers, logic gates, flip flops, or the like and perform signal processing of an input signal.

The clock circuits 630 are composed of buffers, logic gates, flip flops, or the like and supply the clock signal input through the clock input terminal 610 to the data circuits 620.

Power supply voltage is supplied to the power supply terminal 640 from the outside of the semiconductor integrated circuit 600.

The standard-cell power supply wiring 650 supplies the power supply voltage input from the power supply terminal 640 to the data circuits 620 and the clock circuits 630.

In the above-described configuration, the power for use by the data circuits 620 and the clock circuits 630 is supplied from the common standard-cell power supply wiring 650, and the data circuits 620 and the clock circuits 630 are disposed without being clearly separated from each other in the semiconductor integrated circuit 600 (see, for example, FIG. 7. 23 in paragraph 125 of “Design and Trial Manufacture of Digital Integrated Circuit” edited by Kunihiro Asada under the general editorship of VDEC and published on Jun. 26, 2000 by BAIFUKAN Co, Ltd.)

However, when the data circuits 620 operate in synchronization with the input clock signal and thereby consume power, the power supply potential of the data circuits 620 is varied to produce power supply noise. The power supply noise produced in the data circuits 620 propagates through the standard-cell power supply wiring 650 to the clock circuits 630 existing in the vicinity of the data circuits 620.

Therefore, the power supply potential of the clock circuits 630 varies almost as much as the power supply potential of the data circuits 620. If the time at which the power supply potential of the clock circuits 630 varies coincides with the time at which the clock signal input from the PLL circuit or the clock input terminal 610 reaches the clock circuits 630, the delay time of the transistors used in the clock circuits 630 is changed.

All of the transistors included in the data circuits 620 do not operate in synchronization with the clock signal at all times, and different transistors operate in each clock cycle. Therefore, the amount of variation in the power supply potential of the clock circuits 630 differs from one clock cycle to another. As a result, the amount of variation in the delay time of the transistors in the clock circuits 630 varies from one clock cycle to another, which causes degradation of the clock jitter.

If jitter occurs in the clock signal, the timing margin in the data circuits 620 into which the clock signal is input narrows in accordance with the amount of jitter. For example, a failure to latch data (which will be hereinafter referred to as “data mislatch”) due to the degradation of the clock jitter is more likely to occur, causing more malfunctions in the semiconductor integrated circuit.

### SUMMARY OF THE INVENTION

The present invention was made in view of the above problem, and it is therefore an object of the present invention to provide a semiconductor integrated circuit in which degradation of clock jitter is suppressed to reduce malfunctions caused by the clock jitter degradation occurring when a clock signal is propagating in the semiconductor integrated circuit.

In order to overcome the above problem, an inventive semiconductor integrated circuit including a data circuit for performing signal processing of an input signal and a clock circuit for supplying a clock signal to the data circuit includes: data circuit power supply wiring for supplying power supply voltage to the data circuit; clock circuit power supply wiring for supplying power supply voltage to the clock circuit; and a voltage dropper, provided between the data circuit power supply wiring and the clock circuit power supply wiring, for causing a voltage drop for an alternating-current component of a current, wherein the data circuit and the data circuit power supply wiring are formed in a data cell region on a substrate, which is divided into the data cell region and a clock cell region; and the clock circuit and the clock circuit power supply wiring are formed in the clock cell region.

In one aspect of the present invention, in the semiconductor integrated circuit, the voltage dropper includes: other power supply wiring provided in a wiring layer different from a wiring layer in which at least either the data circuit power supply wiring or the clock circuit power supply wiring is provided; and a via for connecting at least either the data circuit power supply wiring or the clock circuit power supply wiring with the other power supply wiring.

In another aspect of the present invention, in the semiconductor integrated circuit, the voltage dropper is a coil.

Then, even if power supply noise is produced in the data circuit, the noise is reduced by the voltage dropper, whereby the amount of variation in the power supply potential of the clock circuit and hence variation in the delay time of the clock circuit are suppressed, thereby reducing the amount of jitter in the clock signal. The reduction in the amount of jitter in the clock signal results in increase in the timing margin in the data circuit, which decreases the probability of occurrence of data mislatch caused by the clock jitter in the data circuit, thereby reducing the probability of malfunctions of the semiconductor integrated circuit.

In another aspect of the present invention, in the semiconductor integrated circuit, a plurality of said clock cell regions are provided on the substrate; and when the clock circuit power supply wiring in each clock cell region needs to be connected with the clock circuit power supply wiring in at least one of the other clock cell regions, these clock circuit power supply wiring are connected by the voltage dropper.

Then, even when the power supply wirings in the clock cell regions are connected with each other, the power supply noise is decreased, making it possible to reduce the amount of jitter in the clock signal.

In another aspect of the present invention, in the semiconductor integrated circuit, only a single clock signal is supplied to the clock circuit in each clock cell region, the single clock signal being different from those supplied to the clock circuits in the other clock cell regions.

Then, since the clock signal in each of the clock cell regions is not affected by the clock signals in the other clock cell regions, the amount of jitter occurring due to the power supply noise is reduced.

In another aspect of the present invention, in the semiconductor integrated circuit, a plurality of said data cell regions are provided on the substrate; and when the data circuit power supply wiring in each data cell region needs to be connected with the data circuit power supply wiring in at least one of the other data cell regions, these data circuit power supply wirings are connected by the voltage dropper.

Then, even when the power supply wirings in the data cell regions are connected with each other, the power supply noise is decreased, making it possible to reduce the amount of jitter in the clock signal.

In another aspect of the present invention, the semiconductor integrated circuit further includes a capacitive element having a capacitance, between the clock circuit power supply wiring and power supply wiring having a potential different from that of the clock circuit power supply wiring.

In another aspect of the present invention, the semiconductor integrated circuit further includes a capacitive element having a capacitance, between the data circuit power supply wiring and power supply wiring having a potential different from that of the data circuit power supply wiring.

Then, the power supply noise transmitted to the clock cell region is reduced further by the capacitance of the capacitive element. Therefore, the amount of variation in the power supply potential of the clock circuit is reduced further, whereby the amount of jitter in the clock signal can be reduced further.

In another aspect of the present invention, in the semiconductor integrated circuit, a plurality of said data cell regions are provided on the substrate; the clock cell region is provided between the data cell regions; and in the clock cell region, data signal wiring for transmitting a signal from the data circuit in each data cell region to the data circuit in at least one of the other data cell regions is orthogonal to clock signal wiring through which the clock circuit transmits the clock signal.

Then, it is possible to prevent the clock signal wiring from being affected by crosstalk noise produced when a signal change occurs in the data signal wiring, whereby the amount of jitter in the clock signal caused by the crosstalk noise can be reduced.

### BRIEF DESCRIPTION OF THE DRAWINGS

FIG. 1 is a block diagram showing the structure of a semiconductor integrated circuit according to a first embodiment of the present invention.

FIG. 2 is a cross-sectional view of a power supply wiring portion in the semiconductor integrated circuit according to the first embodiment of the present invention.

FIG. 3 is a block diagram showing the structure of a semiconductor integrated circuit according to a second embodiment of the present invention.

FIG. 4 is a block diagram showing the structure of a semiconductor integrated circuit according to a third embodiment of the present invention.

FIG. 5 is a block diagram showing the structure of a semiconductor integrated circuit according to a fourth embodiment of the present invention.

FIG. 6 is a block diagram showing the structure of a semiconductor integrated circuit according to a fifth embodiment of the present invention.

FIG. 7 is a block diagram showing the structure of a conventional semiconductor integrated circuit.

### DETAILED DESCRIPTION OF THE INVENTION

Hereinafter, preferred embodiments of the present invention will be described with reference to the accompanying drawings.

### First Embodiment of the Present Invention

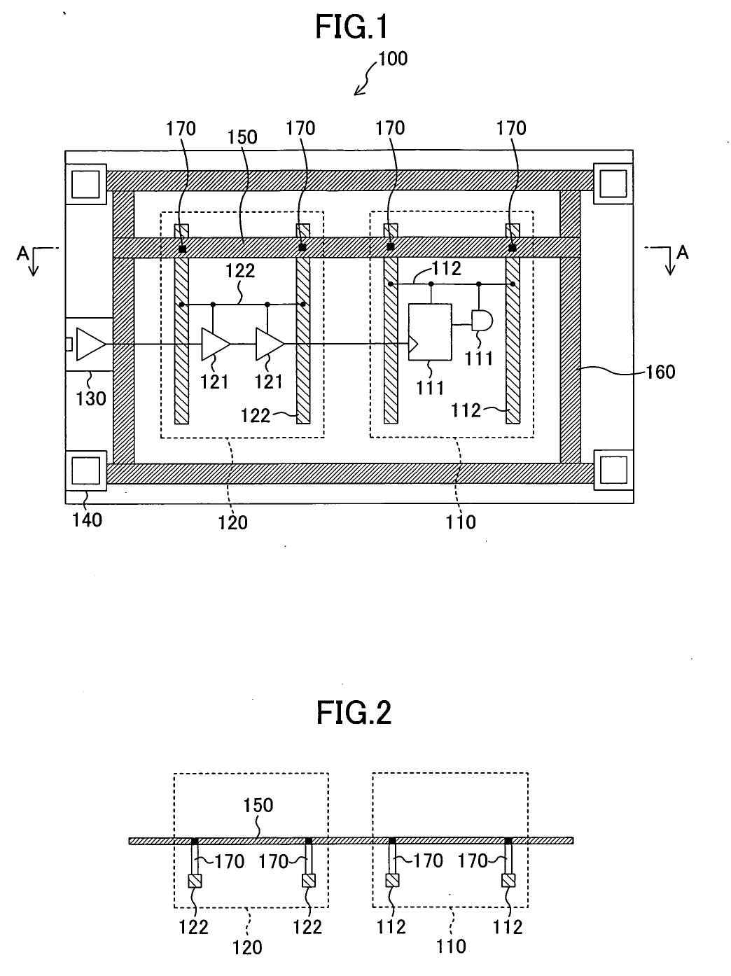

FIG. 1 is a block diagram showing the structure of a semiconductor integrated circuit 100 according to a first embodiment of the present invention. As shown in the figure, the substrate of the semiconductor integrated circuit 100 includes a data cell region 110 and a clock cell region 120, in which circuits are formed.

The data cell region 110 includes data circuits 111 and data circuit power supply wiring 112.

The data circuits 111 are composed of buffers, logic gates, flip flops, or the like and perform signal processing of an input signal.

The data circuit power supply wiring 112 provides the data circuits 111 with power supply voltage.

The clock cell region 120 includes clock circuits 121 and clock circuit power supply wiring 122.

The clock circuits 121 are composed of buffers, logic gates, flip flops, or the like and supply an input clock signal to the data cell region 110.

The clock circuit power supply wiring 122 provides the clock circuits 121 with power supply voltage.

The semiconductor integrated circuit 100 also includes a clock input terminal 130, a power supply terminal 140, upper power supply wiring 150, a ring power supply 160, and vias 170.

A clock signal is input into the clock input terminal 130 from outside the semiconductor integrated circuit 100.

The power supply terminal 140 is connected to the ring power supply 160, while power supply voltage necessary to operate the semiconductor integrated circuit 100 is supplied to the power supply terminal 140 from outside the semiconductor integrated circuit 100.

The upper power supply wiring 150 is formed in a wiring layer that is located at least one level higher than the data circuit power supply wiring 112 and the clock circuit power supply wiring 122.

The ring power supply 160 is formed in a wiring layer that is located at least one level higher than the data circuit power supply wiring 112 and the clock circuit power supply wiring 122 and is connected with the upper power supply wiring 150.

The vias 170 connect the upper power supply wiring 150 and the data circuit power supply wiring 112 and also connect the upper power supply wiring 150 and the clock circuit power supply wiring 122.

FIG. 2 is a cross-sectional view (taken along the line A-A in FIG. 1) showing the power supply wiring and the vias thus structured in the semiconductor integrated circuit 100. This structure allows the clock circuit power supply wiring 122 and the data circuit power supply wiring 112 to be connected with each other by the upper power supply wiring 150 through the vias 170.

Next, the operation of the semiconductor integrated circuit 100 thus structured will be described.

A clock signal input from the clock input terminal 130 passes through the clock circuits 121 in the clock cell region 120 and is input into the data circuits 111 in the data cell region 110.

At this time, since the data circuits 111 operate in synchronization with the clock signal and thereby consume power, the power supply potential of the data circuit power supply wiring 112 is varied to produce power supply noise in one data circuit 111. The power supply noise occurring in the one data circuit 111 would propagate through the data circuit power supply wiring 112 to the clock circuits 121 and the other data circuit 111.

However, since the vias 170 and the upper power supply wiring 150 are present between the data cell region 110 and the clock cell region 120, the power supply noise does not propagate to the clock circuits 121 unless the power supply noise passes through the vias 170 and the upper power supply wiring 150.

The vias 170 in the semiconductor integrated circuit 100 are narrower in wiring width than the clock circuit power supply wiring 122, the data circuit power supply wiring 112, the upper power supply wiring 150 and other wiring, or are made of different material from that of these wirings. It is thus generally well known that the vias 170 have a high resistance value. The power supply noise occurring in the data circuit 111 is therefore reduced by the resistance of the vias 170 and then propagated to the clock circuits 121.

Consequently, the amount of variation in the power supply potential of the clock circuits 121 is smaller than that in the power supply potential in the data cell region 110, whereby changes in the delay time of the clock circuits 121 can be suppressed. The amount of jitter in the clock signal can be thus reduced in the semiconductor integrated circuit 100.

As described above, in this embodiment, the data circuit power supply wiring 112 and the clock circuit power supply wiring 122 are provided in the different regions and connected by the vias whose resistance value is higher than that of the power supply wirings, whereby the power supply noise occurring in the data circuits 111 is reduced and no longer directly affects the clock circuits 121. The amount of variation in the power supply potential of the clock circuits 121 and hence variation in the delay time of the clock circuits 121 can be therefore suppressed, thereby allowing the amount of jitter in the clock signal to be reduced.

The reduction in the amount of jitter in the clock signal results in increase in the timing margin in the data circuits 111, which decreases the probability of occurrence of data mislatch caused by the clock jitter in the data circuits 111, thereby reducing the probability of malfunctions of the semiconductor integrated circuit 100.

In the structure described in this embodiment, the wiring layer of the upper power supply wiring 150 is different from the wiring layer in which the clock circuit power supply wiring 122 in the clock cell region 120 is formed and the wiring layer in which the data circuit power supply wiring 112 in the data cell region 110 is formed. However, even if the power supply wiring is formed in a wiring layer that is different from at least either the clock cell region 120 or the data cell region 110, and the clock cell region 120 and the data cell region 110 are connected by the vias 170, similar effects are obtainable.

Also, even if the connection between the clock cell region 120 and the data cell region 110 is established not by the upper power supply wiring 150 and the vias 170 but by a physical structure or circuit that has the same power-supply-noise reducing effect as the vias 170, similar effects are obtainable. For example, if the wiring length of the upper power supply wiring 150 is significantly long and the upper power supply wiring 150 thus has an impedance, similar effects are obtainable. Furthermore, in cases where impedance elements are used instead of the upper power supply wiring 150 and the vias 170, similar effects are also obtainable.

### Second Embodiment of the Present Invention

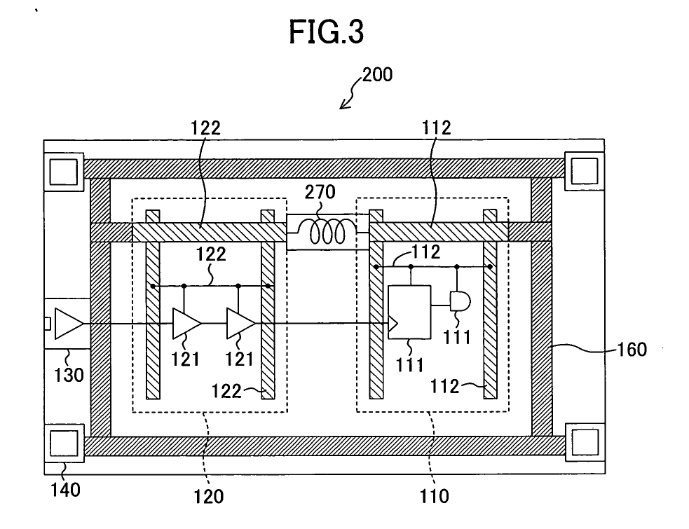

FIG. 3 is a block diagram showing the structure of a semiconductor integrated circuit 200 according to a second embodiment of the present invention. In the below-described embodiments, the components having the same function as those of the first embodiment and the like are designated by the same reference numerals and the description thereof will be thus omitted herein.

The semiconductor integrated circuit 200 is different from the semiconductor integrated circuit 100 of the first embodiment in that the data circuit power supply wiring 112 and the clock circuit power supply wiring 122 are connected with each other by a coil 270 instead of by the vias 170.

The coil 270 is an impedance element and a feature of the coil 270 is that the resistance component thereof is zero while the reactance component thereof has a finite value. It is well known that the resistance component of an impedance element typically causes a voltage drop for the direct-current component of current, while the reactance component thereof typically causes a voltage drop for the alternating-current component of current.

Power supply noise in the data circuits 111 occurs in synchronization with a clock signal input from the clock input terminal 130. Therefore, the power supply potential of the data circuit power supply wiring 112 sharply changes in a short time. As a result, the power supply noise occurring in the data circuits 111 has a high frequency component.

In this embodiment, since the coil 270 has a reactance component, the power supply noise occurring in the data circuits 111 is reduced by the coil 270 and then transmitted to the clock cell region 120.

Therefore, the amount of variation in the power supply potential of the clock circuits 121 existing in the clock cell region 120 is smaller than that in the power supply potential in the data cell region 110, whereby effects similar to those obtainable by the semiconductor integrated circuit of the first embodiment are achievable.

In the power supplied to the clock circuits 121 and the data circuits 111, variation in the potential occurring in a short time is very small and many direct-current components are contained. Therefore, the power supply voltage from the power supply terminal 140 is supplied to the clock circuits 121 and the data circuits 111 without being subjected to a voltage drop caused by the coil 270.

On the other hand, in the semiconductor integrated circuit of the first embodiment, since the upper power supply wiring 150 and the vias 170 have resistance components, the power supply voltage supplied from the power supply terminal 140 is lowered by the upper power supply wiring 150 and the vias 170 and then supplied to the clock circuits 121 and the data circuits 111.

As described above, in the semiconductor integrated circuit of the second embodiment, since the coil 270 does not cause any voltage drop for the direct-current components, the power necessary for the operation of the clock circuits 121 and the data circuits 111 can be supplied without being subjected to a voltage drop.

In the structure described in this embodiment, the clock cell region 120 and the data cell region 110 are connected by the coil 270. However, the present invention is not limited to the coil, so long as the clock cell region 120 and the data cell region 110 are connected by a physical structure or circuit having the same feature as the coil 270, which is that the resistance component thereof is zero while the reactance component thereof has a finite value.

### Third Embodiment of the Present Invention

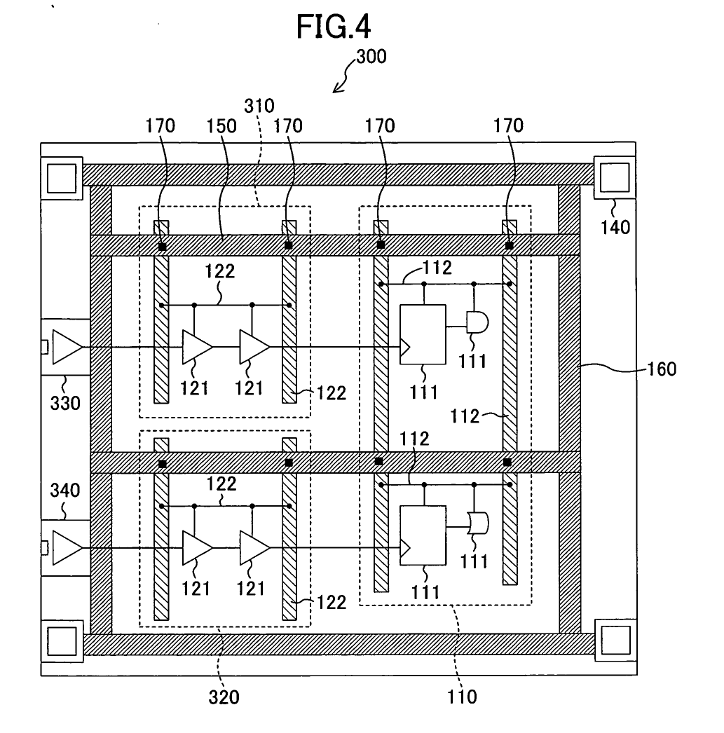

FIG. 4 is a block diagram showing the structure of a semiconductor integrated circuit 300 according to a third embodiment of the present invention. The semiconductor integrated circuit 300 includes a data cell region 110, a first clock cell region 310, and a second clock cell region 320.

The semiconductor integrated circuit of this embodiment is different from the semiconductor integrated circuit of the first embodiment in that two clock signals are input into the semiconductor integrated circuit 300 through a first clock input terminal 330 and a second clock input terminal 340 and that the clock signal input through the first clock input terminal 330 is propagated by clock circuits 121 included in the first clock cell region 310 so as to be input into corresponding data circuits 111 in the data cell region 110 and the clock signal input through the second clock input terminal 340 is propagated by clock circuits 121 included in the second clock cell region 320 so as to be input into corresponding data circuits 111 in the data cell region 110.

The first clock cell region 310 and the second clock cell region 320 are connected by upper power supply wiring 150 and vias 170. This prevents power supply noise occurring in the clock circuits 121 in the first clock cell region 310 from directly propagating to the second clock cell region 320. And power supply noise occurring in the clock circuits 121 included in the second clock cell region 320 does not directly propagate to the first clock cell region 310.

In this way, the clock signal input from the first clock input terminal 330 propagates to the corresponding data circuits 111 in the data cell region 110 without being affected by the clock signal input from the second clock input terminal 340. In the clock signal input from the first clock input terminal 330, the amount of jitter caused by the power supply noise is thus reduced.

Also, the clock signal input from the second clock input terminal 340 propagates to the corresponding data circuits 111 in the data cell region 110 without being affected by the clock signal input from the first clock input terminal 330. In the clock signal input from the second clock input terminal 340, the amount of jitter caused by the power supply noise is thus reduced.

As described above, in this embodiment, not only effects similar to those of the first embodiment are obtainable, but also each of the clock signal input from the first clock input terminal 330 and the clock signal input from the second clock input terminal 340 propagates without being affected by the power supply noise occurring in the clock circuits 121 for the other clock signal, whereby the clock signals in which the amount of jitter is small can be output to the data circuits 111.

In the structure described in this embodiment, two types of clock signals and two clock cell regions are provided. In the case of a structure in which three or more types of clock signals are provided, clock cell regions equal in number to the clock signals may be provided, wherein for clock-signal propagation, each clock cell region only includes one or more clock circuits 121 that propagate one type of clock signal. By this structure, it is possible to reduce the amount of jitter occurring due to variation in the power supply potential caused by the other clock signals.

### Fourth Embodiment of the Present Invention

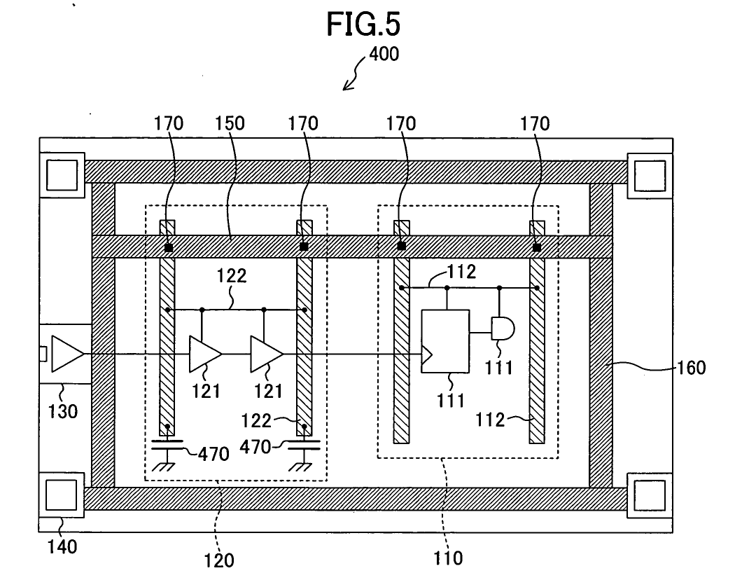

FIG. 5 is a block diagram showing the structure of a semiconductor integrated circuit 400 according to a fourth embodiment of the present invention. The semiconductor integrated circuit 400 is obtained by adding capacitive elements 470 to the semiconductor integrated circuit 100.

The capacitive elements 470 are connected between the clock circuit power supply wiring 122 and power supply wiring having a higher or lower potential than the clock circuit power supply wiring 122. Specifically, in this embodiment, the capacitive elements 470 are connected between the clock circuit power supply wiring 122 and the ground power supply.

Therefore, the power supply noise reduced by the resistance of the vias 170 and propagated to the clock cell region 120 is further reduced by the capacitance of the capacitive elements 470.

Consequently, the amount of variation in the power supply potential of the clock circuits 121 in the clock cell region 120 is reduced further, whereby variation in the delay time of the clock circuits 121 can be suppressed further. In this embodiment, the amount of jitter in the clock signal can be effectively reduced further.

In the structure described in this embodiment, the capacitive elements 470 are included in the clock cell region 120. However, even if the capacitive elements 470 are provided between the data circuit power supply wiring 112 and the ground power supply in the data cell region 110, similar effects are obtainable.

### Fifth Embodiment of the Present Invention

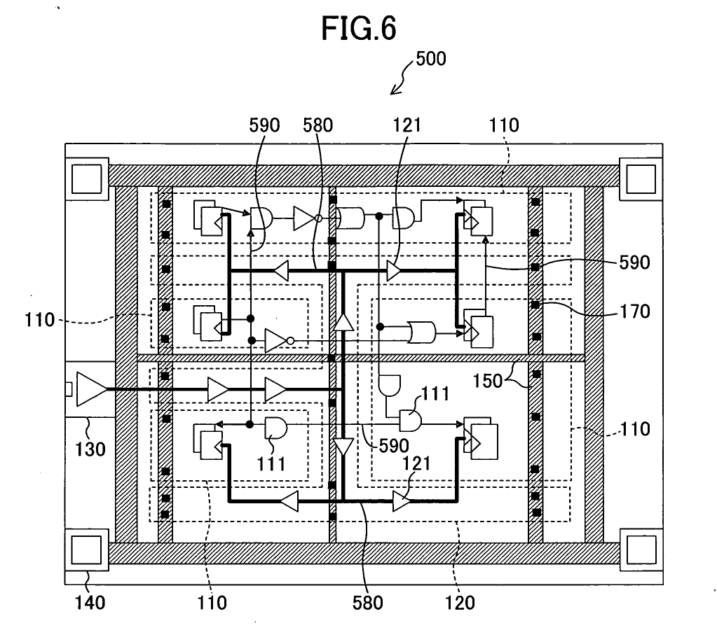

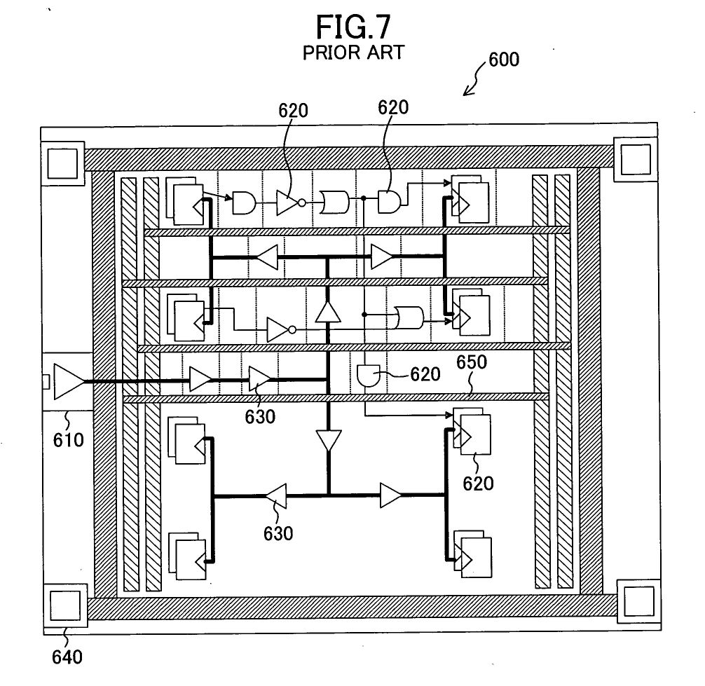

FIG. 6 is a block diagram showing the structure of a semiconductor integrated circuit 500 according to a fifth embodiment of the present invention. In the semiconductor integrated circuit 500, a plurality of data cell regions 110 are included and a clock cell region 120 is provided extending between the data cell regions 110.

In the clock cell region 120, clock circuits 121, clock signal wiring 580 for transmitting clock signals, and data signal wiring 590 for transmitting signals output from data circuits 111 are included. The clock signal wiring 580 and the data signal wiring 590 are disposed so as to be orthogonal to each other.

In the data cell regions 110, the data circuits 111 and the data signal wiring 590 are included. In the other respects, the semiconductor integrated circuit 500 has the same structure as the semiconductor integrated circuit 100 of the first embodiment.

In the semiconductor integrated circuit 500 thus structured, when a clock signal input from the clock input terminal 130 is input into a data circuit 111 in one of the data cell regions 110 through clock circuits 121 in the clock cell region 120 and the clock signal wiring 580, the data circuit 111 operates in synchronization with the input clock signal and outputs a signal to the other data circuits 111 through the data signal wiring 590. At this time, power supply noise occurring in the data circuit 111 in synchronization with the clock signal is reduced because the noise passes through the vias 170 and the upper power supply wiring 150, and the reduced noise is transmitted to the clock circuits 121.

It is thus possible to decrease the amount of jitter occurring in the clock circuits 121 due to the power supply noise, and effects similar to those obtainable by the circuits of the first embodiment are achievable.

It is well known that if the clock signal wiring 580 and the data signal wiring 590 are in parallel with each other, any signal change in the data signal wiring 590 typically results in occurrence of crosstalk noise that is proportional to the value of coupling capacitance between the clock signal wiring 580 and the data signal wiring 590 and that the noise propagates to the clock signal wiring 580. If the time at which this noise occurs coincides with the time at which the clock signal changes, the delay time of the clock signal is varied. This variation in the delay time appears as jitter in the clock signal.

On the other hand, in this embodiment, since the clock signal wiring 580 and the data signal wiring 590 are orthogonal to each other in the clock cell region 120, the value of coupling capacitance between the clock signal wiring 580 and the data signal wiring 590 is decreased, thereby making it possible to prevent the clock signal wiring 580 from being affected by the crosstalk noise produced when a signal change occurs in the data signal wiring 590. In other words, in the fifth embodiment, the amount of jitter in the clock signal occurring due to the effect of crosstalk noise can be reduced.

In each of the foregoing first to fourth embodiments, the semiconductor integrated circuit has a structure in which one clock cell region 120 and one data cell region 110 are provided. However, even if the semiconductor integrated circuit has a structure in which a plurality of clock cell regions 120 or a plurality of data cell regions 110 are provided, similar effects are obtainable. In that case, in the third embodiment, the clock circuit power supply wirings 122 in the clock cell regions 120 may be connected with each other by, e.g., impedance elements such as coils, although an example in which they are connected by the vias 170 has been described in the third embodiment. Then, power supply noise is decreased more effectively to thereby reduce the amount of jitter in the clock signal.

Also, even if the data circuit power supply wirings 112 in the data cell regions 110 are connected with each other by impedance elements, the power supply noise can be likewise effectively reduced.

The semiconductor integrated circuits according to the present invention, which have the effect of suppressing degradation of clock jitter and hence malfunctions in the semiconductor integrated circuits caused by the clock jitter degradation, are effectively applicable to semiconductor integrated circuits or the like that include data circuits for performing signal processing of an input signal and clock circuits for supplying a clock signal to the data circuits.

What is claimed is:

1. A semiconductor integrated circuit including a data circuit for performing signal processing of an input signal and a clock circuit for supplying a clock signal to the data circuit, the semiconductor integrated circuit comprising:
data circuit power supply wiring for supplying power supply voltage to the data circuit;
clock circuit power supply wiring for supplying power supply voltage to the clock circuit; and
a voltage dropper, provided between the data circuit power supply wiring and the clock circuit power supply wiring, for causing a voltage drop for an alternating-current component of a current,
wherein the data circuit and the data circuit power supply wiring are formed in a data cell region on a substrate, which is divided into the data cell region and a clock cell region; and
the clock circuit and the clock circuit power supply wiring are formed in the clock cell region.

2. The semiconductor integrated circuit of claim 1, wherein the voltage dropper includes:
other power supply wiring provided in a wiring layer different from a wiring layer in which at least either the data circuit power supply wiring or the clock circuit power supply wiring is provided; and
a via for connecting at least either the data circuit power supply wiring or the clock circuit power supply wiring with the other power supply wiring.

3. The semiconductor integrated circuit of claim 1, wherein the voltage dropper is a coil.

4. The semiconductor integrated circuit of claim 1, wherein a plurality of said clock cell regions are provided on the substrate; and
when the clock circuit power supply wiring in each clock cell region needs to be connected with the clock circuit power supply wiring in at least one of the other clock cell regions, these clock circuit power supply wirings are connected by the voltage dropper.

5. The semiconductor integrated circuit of claim 4, wherein only a single clock signal is supplied to the clock circuit in each clock cell region, the single clock signal being different from those supplied to the clock circuits in the other clock cell regions.

6. The semiconductor integrated circuit of claim 1, wherein a plurality of said data cell regions are provided on the substrate; and
when the data circuit power supply wiring in each data cell region needs to be connected with the data circuit power supply wiring in at least one of the other data cell regions, these data circuit power supply wirings are connected by the voltage dropper.

7. The semiconductor integrated circuit of claim 1, further comprising a capacitive element having a capacitance, between the clock circuit power supply wiring and power supply wiring having a potential different from that of the clock circuit power supply wiring.

8. The semiconductor integrated circuit of claim 1, further comprising a capacitive element having a capacitance, between the data circuit power supply wiring and power supply wiring having a potential different from that of the data circuit power supply wiring.

9. The semiconductor integrated circuit of claim 1, wherein a plurality of said data cell regions are provided on the substrate;
the clock cell region is provided between the data cell regions; and
in the clock cell region, data signal wiring for transmitting a signal from the data circuit in each data cell region to the data circuit in at least one of the other data cell regions is orthogonal to clock signal wiring through which the clock circuit transmits the clock signal.
